(19) United States
(12) Patent Application Publication
(10) Pub. No.: US 2009/0207901 A1
(43) Pub. Date: Aug. 20, 2009

(54) DELAY CIRCUIT AND METHOD CAPABLE OF PERFORMING ONLINE CALIBRATION

(76) Inventors: Meng-Ta Yang, Miaoli County (TW); Ping-Ying Wang, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 12/033,018

(22) Filed: Feb. 19, 2008

(51) Int. Cl. H03H 7/30; H03K 5/159

(52) U.S. Cl. 375/232

(57) ABSTRACT

A delay circuit includes a first reference delay module, a second reference delay module and a first delay module. The first reference delay module delays a reference signal and generates a first reference delayed signal, and the second reference delay module delays the reference signal and generates a second reference delayed signal according to a reference control signal and the first reference delayed signal. The first delay module delays a first input signal and generates a first output signal according to a first control signal and the second reference delayed signal.

### BACKGROUND

The embodiments relate to delay circuits and methods, and more particularly, to delay circuits capable of performing online calibration.

Timing control is an important technology that has various applications. For example, the technology can be adopted to accurately control the timing of rising edges and falling edges of a driving signal, which drives a laser diode responsible for writing data onto an optical disc.

Generally speaking, timing control comprises applying a delay to an input signal to generate an output signal, where the delay is provided by combinational logic. However, one problem of this method is that it is difficult to precisely calculate the exact amount of delay during the circuit design stage. Furthermore, the amount of delay also changes due to process, temperature, and supplied power variations. Therefore, it is necessary to provide a solution that allows an input signal to be precisely delayed for a desired amount of time.

### SUMMARY

According to one embodiment of the claimed invention, a delay circuit comprises a first reference delay module, a second reference delay module, and a first delay module. The first reference delay module delays a reference signal and generates a first reference delayed signal, and the second reference delay module delays the reference signal and generates a second reference delayed signal according to a reference control signal and the first reference delayed signal. The first delay module delays a first input signal and generates a first output signal according to a first control signal and the second reference delayed signal.

According to another embodiment of the claimed invention, a delay circuit comprises a reference delay module, a first delay module, a second delay module, and a multiplexer. The reference delay module is utilized for delaying a reference signal and generating a reference delayed signal. The first delay module is utilized for delaying a first input signal and generating a first output signal according to a first control signal, the reference signal, and the reference delayed signal. The second delay module is utilized for delaying a second input signal and generating a second output signal according to a second control signal, the reference signal, and the reference delayed signal. The multiplexer is utilized for selecting one of the first output signal and the second output signal to output.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a delay circuit according to an embodiment.

FIG. 2 shows the delay conversion unit according to an embodiment.

FIG. 3 shows the rough delay unit according to an embodiment.

FIG. 4 shows the fine delay unit according to an embodiment.

FIG. 5 shows a delay circuit according to another embodiment.

### DETAILED DESCRIPTION

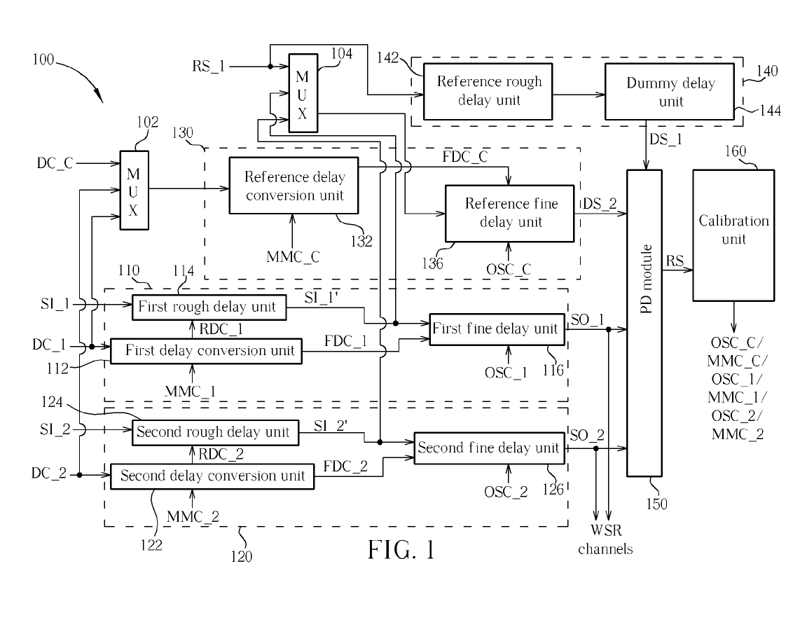

FIG. 1 shows a delay circuit 100 according to an embodiment. The delay circuit 100 has a first reference delay module 140, a second reference delay module 130, and a first delay module 110. The first reference delay module 140 is arranged to delay a reference signal RS_1 and generate a first reference delayed signal DS_1. The second reference delay module 130 is arranged to delay the reference signal RS_1 and generate a second reference delayed signal DS_2 according to a reference control signal DC_C and the first reference delayed signal DS_1 . The first delay module 110 is arranged to delay a first input signal SI_1 and generate a first output signal SO_1 according to a first control signal DC_1 and the second reference delayed signal DS_2. The delay circuit 100 also has a calibration unit 160 to generate a reference calibration signal (OSC_C or MMC_C) to control the second reference delay module 130 according to the first reference delayed signal DS_1 and the second reference delayed signal DS_2. Namely, when the delay circuit 100 starts to operate, the reference signal RS_1 is respectively delayed by a reference rough delay unit 142 and the reference fine delay unit 136 to respectively generate the first reference delayed signal DS_1 and the second reference delayed signal DS_2. Then the reference fine delay unit 136 is calibrated by the reference calibration signal (OSC_C or MMC_C) from the calibration unit 160 to produce the same delay effect of the reference rough delay unit 142.

It means that the second reference delay module 130 is aligned by the first reference delay module 140 in this condition, and in order to get good align effect, the reference signal RS_1 processed by the reference rough delay unit 142 and the reference fine delay unit 136 should be a simple and periodic signal.

For example, when the reference rough delay unit 142 is implemented by flip-flops or registers to produce a target delay of ‘1T’ (T represents the basic delay time unit), and the fine delay unit 136 is implemented by inverters to produce the same target delay ‘1T’, the required amount of inverters to produce the target delay ‘1T’ is decided by the calibration between the first reference delayed signal DS_1 and the second reference delayed signal DS_2. Generally speaking, the time unit of delay caused by the reference rough delay unit 142 is clock cycle, and the time units of delay caused by the fine delay unit 136 is RC delay. The duration of clock cycle is greater than RC delay; therefore the delay caused by the reference rough delay unit 142 (clock cycle) can be measured precisely from delay caused by the fine delay unit 136 (RC delay).

It is noted that the reference calibration signals OSC_C and MMC_C are respectively arranged to calibrate the offset or mismatch of the signals to be processed, and the reference control signal DC_C is arranged to select the calibration of offset or mismatch.

After the calibration of the second reference delay module 130 according to the first reference delay module 140 is finished, the first delay module 110 starts to delay the first input signal SI_1. The calibration unit 160 thereby generates a first calibration signal (OSC_1 or MMC_1 ) to control the first delay module 110 according to the second reference delayed signal DS_2 and the first output signal SO_1.

When the first delay module 110 generates the first output signal SO_1, the second reference delay module 130 receives the first control signal DC_1 and a first rough delay signal SI_{—}1’, wherein the first control signal DC_1 is processed for controlling the reference fine delay unit 136 to delay the first rough delay signal SI_{—}1’. It means that the second reference delay module 130 receives the first control signal DC_1 to delay a first rough delay signal SI_{—}1’ to be the second reference delayed signal DS_2. Meanwhile, the calibration unit 160 keeps the same reference calibration signal (OSC_C or MMC_C) to control the second reference delay module 130, wherein the same reference calibration signal (OSC_C or MMC_C) is previously used in calibrating the second reference delay module 130 according to the first reference delay module 140.

Namely, when the delay circuit 100 calibrates the first input signal SI_1, the second reference delay module 130 and first delay module 110 have to use the same control signal (i.e. the first control signal DC_1) and the same source signal (i.e. the first rough delay signal SI_{—}1’).

In the delay circuit 100, the multiplexer 102 and 104 are respectively arranged to select the first control signal DC_1 and the first rough delay signal SI_{—}1’ to be inputted into the second reference delay module 130. The first rough delay signal SI_{—}1’ is generated from a first rough delay unit 114, then be inputted into the reference fine delay unit 136 of the second reference delay module 130 and a first fine delay unit 116 of the first delay module 110.

For delaying more input signals, the delay circuit 100 further has a second delay module 120 to delay a second input signal SI_{—}2 and generate a second output signal SO_2 according to a second control signal DC_2 and the second reference delayed signal DS_2. The second delay module 120 delays the second input signal SI_2 according to the second calibration signal (OSC_2 or MMC_2) from the calibration unit 160.

The delay (calibration) process of the second input signal SI_2 is similar to the delay (calibration) process of the first input signal SI_1 . In this situation, the second reference delay module 130 receives a second rough delay signal SI_{—}2’ for being delayed by the reference fine delay unit 136. The second rough delay signal SI_{—}2’ is generated from a second rough delay unit 124, and then be inputted into the reference fine delay unit 136 of the second reference delay module 130 and a second fine delay unit 126 of the second delay module 120.

It is noted that because the second reference delayed signal DS_2 is already calibrated according to the reference calibration signal (OSC_C or MMC_C) described above, the second reference delayed signal DS_2 can be used to calibrate the second output signal SO_2 directly when delay the second input signal SI_2.

Explaining the FIG. 1 in detail, the second reference delay module 140 has the reference rough delay unit 142 and a dummy delay unit 144. The reference rough delay unit 142 can generally apply a reference rough delay (equals N times the basic delay time unit T) to the reference signal RS_1 to generate the first reference delayed signal DS_1 , wherein N is an integer. The dummy delay unit 144 is arranged to additionally apply a delay to the reference signal RS_1 to generate the first reference delayed signal DS_1, therefore the delay offsets between the second reference delay module 140 and the first reference delay module 130 can be substantially matched.

Except the reference fine delay unit 136, the first reference delay module 130 has a reference delay conversion unit 132. The reference delay conversion unit 132 generates the reference fine delay control signal FDC_C to be inputted into the reference fine delay unit 136 according to the reference control signal DC_C and a reference conversion relationship. The reference fine delay control signal FDC_C is then utilized to control the reference fine delay unit 136 to apply the reference delay to the first reference signal RS_1 , and the second reference delayed signal DS_2 is generated thereby.

As mentioned to the reference conversion relationship, assuming that the duration of the first delay equals X1*T, where T represents the basic delay time unit and X1 is a positive number having a first part X1 a and a second part X1b. For example, the first part X1a and second part X1b are the integral part and fractional part of X1, respectively. Thus, the reference conversion relationship is adjusted by a ratio between the number of utilized inverters in the reference fine delay unit 136 and the value of the fractional part.

Similarly, the first delay module 110 and the second delay module 120 have a first delay conversion unit 112 and a second delay conversion unit 122, respectively. The first delay conversion unit 112 and the second delay conversion unit 122 operate similar to the reference delay conversion unit 132. Moreover, the first delay conversion unit 112 and the second delay conversion unit 122 respectively generates a first rough delay control signal RDC_1 and a second rough delay control signal RDC_2 to respectively control the first rough delay unit 114 and the second rough delay unit 124.

Namely, the first delay conversion unit 112 generates a first fine delay control signal FDC_1 to be inputted into the first fine delay unit 116 according to the first control signal DC_1 and a reference conversion relationship. The reference fine delay control signal FDC_1 is then utilized to control the first fine delay unit 116 to apply the delay to the first rough delay signal SI_{—}1’ so as to generate the first output signal SO_1. Similarly, the second delay conversion unit 122 also generates a second fine delay control signal FDC_2 to be inputted into the second fine delay unit 126, and the relative description of the operation is omitted for simplicity.

The delay circuit 100 also has a PD (phase detecting) module 150 to compare signals including the first reference delayed signal DS_1, the second reference delayed signal DS_2, the first output signal SO_1, and the second output signal SO_2 to generate a comparison result RS which represents the difference between the two compared signals. The calibration unit 160 then functions according to the comparison result RS.

For example, when the comparison result RS shows that the second reference delayed signal DS_2 leads the first reference delayed signal DS_1, the calibration unit 160 utilizes the reference calibration signal OSC_C of offset to control the delay offset of the reference fine delay unit 136. Ideally, this delay (calibration) is performed when the phase of the first reference delayed signal DS_1 substantially matches the phase of the second reference delayed signal DS_2.

In the condition of comparing the first reference delayed signal DS_1 and the second reference delayed signal DS_2 are utilized to be compared by the PD module 150, the calibration unit 160 generates the reference calibration signal (OSC_C or MMC_C). The reference calibration signal includes either an offset calibration signal OSC_C to adjust the offset of the reference fine delay unit 136, or generates a mismatch calibration signal MMC_C to adjust the reference conversion relationship of the reference delay conversion unit 132. The conditions of comparing the second reference delayed signal DS_2 with the first output signal SO_1, and comparing the second reference delayed signal DS_2 with the second output signal SO_2 are similar to comparing the first reference delayed signal DS_1 and the second reference delayed signal DS_2, thus the description of these conditions are omitted for simplicity.

Therefore, the delay circuit 100 can be used in three conditions, which are comparing DS_1 with DS_2, comparing DS_2 with SO_1, and comparing DS_2 with SO_2. For each condition, there are two kinds of calibration, offset calibration and mismatch calibration, to be selected.

During the delay circuit 100 operates, the first delay module 110 and the second delay module 120 works without interference to each other. Therefore, online calibration is possible for the delay circuit 100.

The delay circuit 100 can be used in many devices. For example, the delay circuit 100 can be used in an optical disc drive, thus the two input signal SI_1 and SI_2 are the signals used for the WSR (write strategy) channels to control the write power of a laser diode of the optical disc drive. The two control signals DC_1 and DC_2 are generated by a write strategy circuit of the optical disc drive to control the delay time of the input signals SI_1 and SI_2, respectively; and the two output signals SO_1 and SO_2 are outputted to the WSR channels respectively to control the write power.

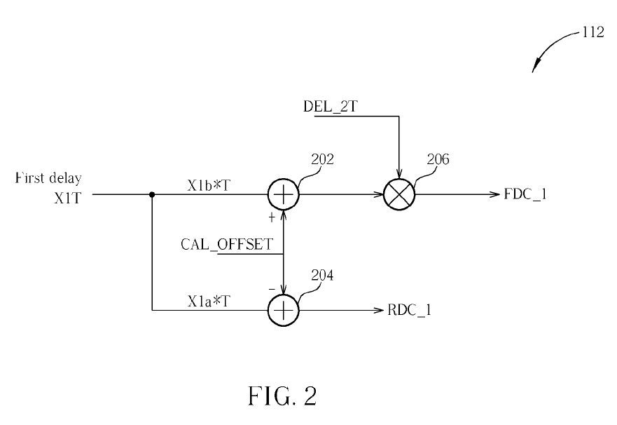

FIG. 2 shows the first delay conversion unit 112. As shown in FIG. 2, the first delay conversion unit 112 includes two adder 202 and 204, and a multiplier 206. An offset calibration signal CAL_OFFSET is utilized for calibrating an original offset between two circuits which respectively transmits the rough delay control signal RDC_1 and the first fine delay control signal FDC_1. The first rough delay control signal RDC_1 (that is the first part X1a*T) controls the amount of delay based on the number of clock pulses; and the first fine delay control signal FDC_1 (that is the second part X1b*T) controls the amount of delay based on the number of inverters (or delay cells). A delay control signal DEL_2T means that the delay line is 2T, which means the allowable range of the second part X1b*T (FDC_1) is between 0*T and 2*T. In practice, the second part X1b*T may be added 1*T for special purpose, therefore if the delay line is 1*T, the calibration may be failed. As a result, the 2T delay line is preferred in this circuit.

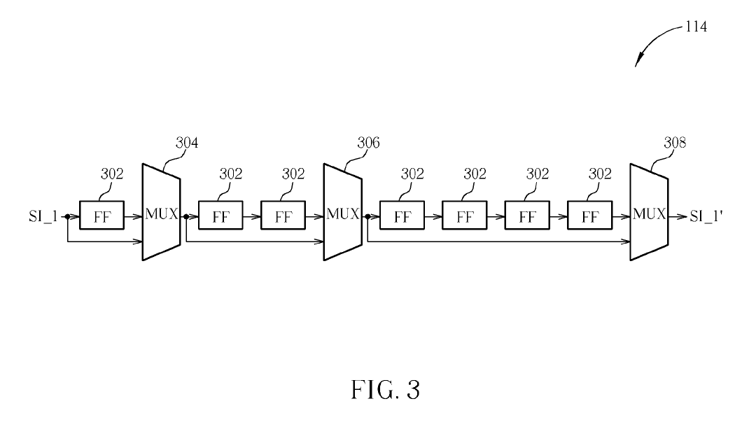

FIG. 3 shows the first rough delay unit 114. As shown in FIG. 3, the first rough delay unit 114 includes a plurality of flip-flops 302 and a plurality of multiplexers 304, 306 and 308. As a person skilled in this art can readily understand operations of the circuit components included in the first rough delay unit 114, therefore further description is omitted.

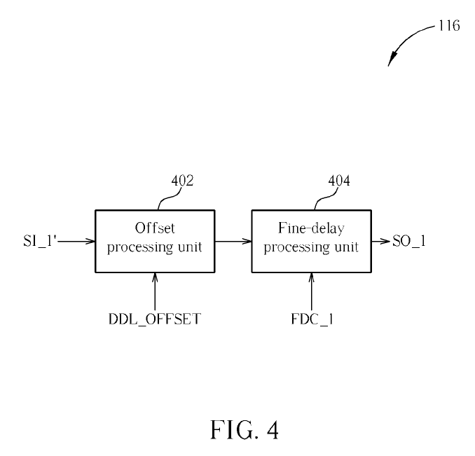

FIG. 4 shows the first fine delay unit 116. As shown in FIG. 4, the fine delay unit 116 includes an offset processing unit 402 and a fine-delay processing unit 404. The offset processing unit 402 is used to calibrate the offset of the first rough delay signal SI_{—}1’ according to an offset signal DDL_OFFSET. The offset processing unit 402 is an optional unit and can be removed from the fine delay unit 116. The fine-delay processing unit 404 generates the first output signal SO_1 according to the first fine delay control signal FDC_1.

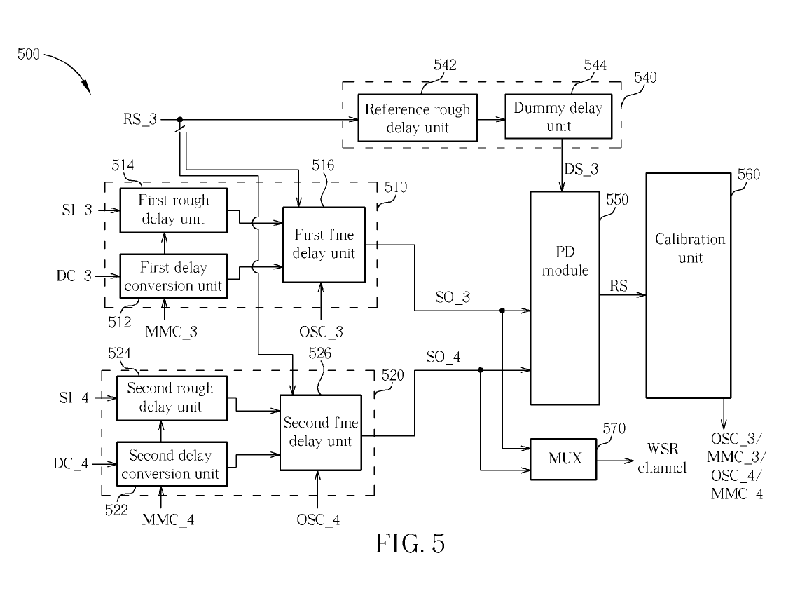

FIG. 5 shows a delay circuit 500 according to another embodiment. The delay circuit 500 has a reference delay module 540, a first delay module 510, a second delay module 520, and a multiplexer 570. The reference delay module 540 is arranged to delay a reference signal RS_3 and generate a reference delayed signal DS_3. The first delay module 510 is arranged to delay a first input signal SI_3 and generate a first output signal SO_3 according to a first control signal DC_3. The second delay module 520 is arranged to delay a second input signal SI_4 and generate a second output signal SO_4 according to a second control signal DC_4. The multiplexer 570 is arranged to select one of the first output signal SO_3 and the second output signal SO_4 to output to a WSR channel.

It is noted that the reference delay module 540, the first delay module 510, and the second delay module 520 are respectively implemented similar to the reference delay module 140, the first delay module 110, and the second delay module 120 in FIG. 1. Namely, the reference delay module 540 has a reference rough delay unit 542 and a dummy delay unit 544; the first delay module 510 has a first delay conversion unit 512, a first rough delay unit 514, and a first fine delay unit 516; the second delay module 520 has a second delay conversion unit 522, a second rough delay unit 524, and a second fine delay unit 526. The relative descriptions are omitted for simplicity.

Moreover, similar to the delay circuit of the delay circuit 100 of FIG. 1, the delay circuit 500 also has a PD (phase detecting) module 550 to compare signals including the reference delayed signal DS_3, the first output signal SO_3, and the second output signal SO_4 to generate a comparison result RS which represents the difference between the two compared signals. The delay circuit 500 also has a calibration unit 560 to generate a first calibration signal (OSC_3 or MMC_3) to control the first delay module 510 according to the reference delayed signal DS_3 and the first output signal SO_3. The calibration unit 560 also generates a second calibration signal (OSC_4 or MMC_4) to control the second delay module 520 according to the reference delayed signal DS_3 and the second output signal SO_4.

Namely, when the delay circuit 500 starts to operate, the reference signal RS_3 is respectively delayed by the reference delay module 540 and the first fine delay unit 516 of the first delay module 510 to respectively generate the reference delayed signal DS_3 and the first output signal SO_3. Therefore, the first delay module 510 is calibrated by the first calibration signal (OSC_3 or MMC_3) from the calibration unit 560 to produce the same delay effect of the reference delay module 540.

It means that the first delay module 510 is aligned by the reference delay module 540 in this condition. Therefore the first delay module 510 receives the simple and periodic signal (the reference signal RS_3) and is controlled by the first control signal DC_3. The simple and periodic signal (the reference signal RS_3) prevents the alignment between the first delay module 510 and the reference delay module 540 from interference.

After the calibration (alignment) of the first delay module 510 according to the reference delay module 540 is finished, the first delay module 510 starts to delay the first input signal SI_3 according to the first control signal DC_3 and the first calibration signal (OSC_3 or MMC_3). Meanwhile, the calibration unit 560 keeps the same first calibration signal (OSC_3 or MMC_3) to control the first delay module 510, wherein the same first calibration signal (OSC_3 or MMC_3) is previously used in calibrating the first delay module 510 according to the reference delay module 540. Therefore, the first output signal SO_3 is calibrated with a target delay.

Then, the second input signal SI_4 is calibrated by the second delay module 520 to generate the second output signal SO_4. This calibration process is similar to the calibration process of the first input signal SI_3. Namely, the second delay module 520 firstly receives the reference signal RS_3 to be calibrated according to the alignment with the reference delay module 540, and then gets the second calibration signal (OSC_4 or MMC_4). Then, the second delay module 520 uses the second calibration signal (OSC_4 or MMC_4) to calibrate the second input signal SI_4 to generate the second output signal SO_4.

In this embodiment, the multiplexer 570 selects one of the first output signal SO_3 and the second output signal SO_4 to output to the WSR channel according to which output signal calibration is finished. It is noted that the first delay module 510 and the second delay module 520 have to receive the same input signal for the multiplexer outputting one of the output signal.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A delay circuit comprising:
a first reference delay module delaying a reference signal and generating a first reference delayed signal;
a second reference delay module delaying the reference signal and generating a second reference delayed signal according to a reference control signal and the first reference delayed signal; and
a first delay module delaying a first input signal and generating a first output signal according to a first control signal and the second reference delayed signal.

2. The delay circuit of claim 1, further comprising a calibration unit to generate a reference calibration signal to control the second reference delay module according to the first reference delayed signal and the second reference delayed signal.

3. The delay circuit of claim 2, wherein the calibration unit generates a first calibration signal to control the first delay module according to the second reference delayed signal and the first output signal.

4. The delay circuit of claim 1, wherein when the first delay module generating the first output signal, the second reference delay module receives the first control signal to delay the second reference delayed signal.

5. The delay circuit of claim 4, wherein when the first delay module generating the first output signal, the second reference delay module delays a first rough delay signal to be the second reference delayed signal.

6. The delay circuit of claim 1, further comprising a second delay module delaying a second input signal and generating a second output signal according to a second control signal and the second reference delayed signal.

7. A delay circuit comprising:
a reference delay module delaying a reference signal and generating a reference delayed signal;
a first delay module delaying a first input signal and generating a first output signal according to a first control signal, the reference signal, and the reference delayed signal;
a second delay module delaying a second input signal and generating a second output signal according to a second control signal, the reference signal, and the reference delayed signal; and
a multiplexer selecting one of the first output signal and the second output signal to output.

8. The delay circuit of claim 7, further comprising a calibration unit to generate a first calibration signal to control the first delay module according to the reference delayed signal and the first output signal.

9. The delay circuit of claim 8, wherein the calibration unit generates a second calibration signal to control the second delay module according to the reference delayed signal and the second output signal.

10. The delay circuit of claim 7, wherein the second delay module receives the reference signal for being calibrated with the reference delay module before generating the second output signal.

11. A method to delay a signal, comprising:
delaying a reference signal and generating a first reference delayed signal;
delaying the reference signal and generating a second reference delayed signal according to a reference control signal and the first reference delayed signal; and
delaying a first input signal and generating a first output signal according to a first control signal and the second reference delayed signal.

12. The method of claim 11, further comprising generating a reference calibration signal according to the first reference delayed signal and the second reference delayed signal to control delaying the reference signal and generating the second reference delayed signal.

13. The method of claim 11, further comprising generating a first calibration signal according to the first reference delayed signal and the first output signal to control delaying the first input signal and generating the first output signal.

14. The method of claim 11, wherein when delaying the first input signal to be the first output signal, further comprising delaying the second reference delayed signal according to the first control signal.

15. The method of claim 11, wherein when delaying the first input signal to be the first output signal, further comprising delaying a first rough delay signal to be the second reference delayed signal.

16. The method of claim 11, further comprising delaying a second input signal and generating a second output signal according to a second control signal and the second reference delayed signal.

17. A method to delay a signal, comprising:
delaying a reference signal and generating a reference delayed signal;
delaying a first input signal and generating a first output signal according to a first control signal, the reference signal, and the reference delayed signal;
delaying a second input signal and generating a second output signal according to a second control signal, the reference signal, and the reference delayed signal; and
outputting one of the first output signal and the second output signal.

18. The method of claim 17, further comprising generating a first calibration signal according to the reference delayed signal and the first output signal to control the first delay module.

19. The method of claim 17, further comprising generating a second calibration signal according to the reference delayed signal and the second output signal to control the second delay module.

20. The method of claim 17, further comprising receiving the reference signal for being calibrated with the reference delay signal before generating the second output signal.
